(19) United States
(12) Patent Application Publication
(10) Pub. No.: US 2012/0199028 A1
(43) Pub. Date: Aug. 9, 2012

(54) PREPARING LITHOGRAPHIC PRINTING PLATES

(76) Inventors: Mathias Jarek, Bad Gandersheim (DE); Domenico Balbinot, Osterode (DE)

(21) Appl. No.: 13/022,714

(22) Filed: Feb. 8, 2011

(51) Int. Cl. B41N 3/00; G03F 7/26

(52) U.S. Cl. 101/463.1; 430/302

(57) ABSTRACT

Negative-working lithographic printing plate precursors can be imaged and then processed using a single processing solution in a processing apparatus without rinsing or gumming before the resulting lithographic printing plates are used for printing. The single processing solution (developer) comprises at least 2.5 weight % of a nonionic surfactant having an HLB value greater than 15 and at least 5 weight % of a polar organic solvent. Processing is accomplished without replenishment and reduced sludge formation is seen at the end of the processing cycle.

### FIELD OF THE INVENTION

This invention relates to a method for preparing lithographic printing plates using a single processing solution that both develops and gums the imaged negative-working lithographic printing plate precursors.

### BACKGROUND OF THE INVENTION

In lithographic printing, ink receptive regions, known as image areas, are generated on a hydrophilic surface. When the surface is moistened with water and ink is applied, the hydrophilic regions retain the water and repel the ink the ink receptive regions accept the ink and repel the water. The ink is then transferred to the surface of suitable materials upon which the image is to be reproduced. In some instances, the ink can be first transferred to an intermediate blanket that in turn is used to transfer the ink to the surface of the materials upon which the image is to be reproduced.

Lithographic printing plate precursors useful to prepare lithographic (or offset) printing plates typically comprise one or more imageable layers applied over a hydrophilic surface of a substrate. The imageable layer(s) can comprise one or more radiation-sensitive components dispersed within a suitable binder. Following imaging, either the exposed regions or the non-exposed regions of the imageable layer(s) are removed by a suitable developer, revealing the underlying hydrophilic surface of the substrate. If the exposed regions are removed, the element is considered as positive-working. Conversely, if the non-exposed regions are removed, the element is considered as negative-working. In each instance, the regions of the imageable layer(s) that remain are ink-receptive, and the regions of the hydrophilic surface revealed by the developing process accept water or aqueous solutions (typically a fountain solution), and repel ink.

“Laser direct imaging” methods (LDI) are used to directly form an offset printing plate or printing circuit board using digital data from a computer, and provide numerous advantages over the previous processes using masking photographic films. There has been considerable development in this field from more efficient lasers, improved imageable compositions and components thereof.

Various radiation-sensitive compositions are used in negative-working lithographic printing plate precursors as described for example in U.S. Pat. Nos. 6,309,792 (Hauck et al.), 6,893,797 (Munnelly et al.), 6,727,281 (Tao et al.), 6,899,994 (Huang et al.), and 7,429,445 (Munnelly et al.), U.S. Patent Application Publications 2002/0168494 (Nagata et al.), 2003/0118939 (West et al.), and EP Publications 1,079,276A2 (Lifka et al.) and 1,449,650A2 (Goto et al.).

After imaging, negative-working lithographic printing plate precursors are generally developed (processed) to remove the non-imaged (non-exposed) regions of the imageable layer. It is common to rinse the developed precursors to remove excess developer. It is also common to “gum” the developed precursor to provide a protective layer over the imaged surface. Individual developers, rinsing solutions, and gumming solutions are typically used for such processes. Such multi-step processing methods are described for example in EP 1,947,514 (Inno et al.) for use to prepare lithographic printing plates from UV imaged elements.

Simplified processing solutions have been developed to be the only solution that is used to contact the precursor before printing. For example, U.S. Patent Application Publication 2009/0263746 (Ray et al.) describes the use of a single processing solution having a pH of 2 to 11 and containing an anionic surfactant to develop the imaged precursor as well as provide a protective coating over the printing surface. The processing solution can be applied in various ways including spraying, jetting, dipping, immersing, coating, and wiping techniques. Excess processing solution can be collected in a tank and used repeatedly, and replenished with “fresh” processing solution having the same or more concentrated form, which can be diluted with water.

EP Publication 1,091,253 (Yosida et al.) describes a method for processing by immersion in which the supply of developing is maintained at an optimum volume level by replenishing the developer with water (see FIG. 2 and [0054]-[0056]).

EP Publication 2,045,662 (Oohashi) describes processing with a low pH developer that can be replenished in an automatic processor to maintain developer volume using fresh developer or water. Developer can be sprayed onto imaged precursors.

In addition, EP Publications 1,788,429 (Loccufier et al.), EP 1,788,430 (Loccufier et al.), 1,788,431 (Van Damme et al.), and 1,788,434 (Van Damme et al) describe the use of a gum as a developer, and it can be replenished using fresh gum, water, or a buffer based on the concentration of active products in the gum, gum viscosity, conductivity, or pH, or evaluation of solvent or water from the gum developer.

While some processing methods in the art require direct replenishment of the developer to maintain its volume and activity, other commercial processes simply use up developer from a container without any replenishment. This is the case for Agfa's commercial Azura processing technology (information available from Agfa's web site) that uses a 20-liter canister containing the developer that is used without any replenishment. The problem with this type of processing is that the cycle time is quite short. If the used developer is recycled to the canister, the developer solids content can increase (perhaps up to two times original concentration) because water has evaporated or been carried out by processed lithographic printing plates. As the solids content increases, apparatus rollers and processed lithographic printing plates are contaminated with dried residue, requiring additional cleaning or discarding mined lithographic printing plates.

While simplified processing with a single processing solution to accomplish development, rinsing, and gumming in a single step sounds easy, it is not. It is a challenge to design such a processing system for use with various negative-working lithographic printing plate precursors having various imaging compositions. The most challenging aspects for simplified processing are:

developing and gumming much occur in one step without any post-rinsing operation or additional gumming steps,

easy restart of processing even with highly loaded (contaminated) processing solutions,

good ink receptivity of the imaged regions even with highly loaded processing solutions, and

clean printing plate evaluation in the non-imaged regions after storage for several days even with highly loaded processing solution (no post-development after storage), indicative of high resistance to chemical solvents.

The solution used to develop or process imaged precursors must be carefully designed with necessary surfactants and solvents to solubilize or emulsify the chemical components that are removed from the imaged precursors, which chemical components generally include polymeric binders, free radical polymerizable compounds, photoinitiators, and radiation absorbing compounds. Most of these compounds are not water-soluble and thus become sludge in a processing bath.

EP 1,868,036 (Baumann et al.) describes the use of a combined developer/gum solution to process developed lithographic printing plate precursors. This processing solution can include organic solvents, either or both anionic and nonionic surfactants, and various other conventional components, and the processing solution is replenished as needed. Similar processing is described in EP 1,755,002 (Adachi).

Other processing solutions have been designed for both development and gumming (finishing) by including one or more surfactants and optionally organic solvents including polar organic solvents. U.S. Pat. No. 4,381,340 (Walls) describes processing of imaged diazo-based elements using nonionic surfactants having an HLB value greater than 17.

There is a continuing desire in the lithographic industry to simplify processing without having to significantly redesign processing apparatus. One common processing technique is to spray the processing solution onto the imaged precursors from a reservoir or canister containing replenished processing solution. Such techniques result in considerable evaporation of water from the processing solution. This evaporation leads to a considerable increase in the concentration of processing solution components and “load” from removed precursor coatings so that the concentration at the end of the processing cycle could be doubled and sludge is increased. In such concentrated solutions, the conventional surfactants used to emulsify removed coating chemicals lose their effectiveness, thereby increasing sludge even more. Moreover, if the processing solutions contain water-insoluble organic solvents used to dissolve the coating chemicals, and as the chemical and organic solvent concentrations increase, phase separation between water and organic solvents also increases.

Sludge and phase separation decrease the effectiveness of processing and unwanted residue can be found on the lithographic printing plates. Such residue creates defects in printed images. Other negative effects of the increase in chemical concentration include dried residue on processing rollers and reduced cycle time (less lithographic printing plates prepared for a given volume of processing solution).

Thus, there is a need to improve processing using a simplified processing solution that both develops and gums imaged precursors, while reducing the amount of sludge in the processing solution.

### SUMMARY OF THE INVENTION

The present invention provides a method for preparing a plurality of lithographic printing plates, comprising:

imaging a plurality of negative-working lithographic printing plate precursors comprising free radical imaging chemistry to provide a plurality of imaged precursors,

processing each of the imaged precursors in a processing apparatus comprising a working strength processing solution that comprises at least 2.5 weight % of a nonionic surfactant having a HLB value greater than 15 and at least 5 weight % of a polar organic solvent, by applying the working strength processing solution to each imaged precursor to provide a lithographic printing plate having a printing surface,

wherein the processing solution is not replenished during processing of the plurality of imaged precursors, the processing solution is designed to both develops each imaged precursor and to provide a protective coating over the printing surface of the lithographic printing plate, and the plurality of imaged precursors are contacted with no additional solutions after processing with the working strength processing solution before they are used for lithographic printing.

In some embodiments, the method also comprises using the lithographic printing plate for lithographic printing without contact with any additional solutions after processing.

The present invention is directed to the noted problems with a simplified, single-step method for imaging and processing negative-working lithographic printing plate precursors. Processing cycle time is maximized and sludge formation is reduced so that it is less likely that residue is deposited on processed lithographic printing plates and apparatus rollers. Cleaning can be carried out less frequently. The working strength processing solution used in this invention both develops the imaged precursor and provides a protective gum.

These advantages are achieved in the method by using a unique working strength processing solution that includes at least 2.5 weight % of a nonionic surfactant that has an HLB value greater than 15, and at least 5 weight % of a polar organic solvent. While both of these features are described individually in the literature, this unique combination of features provides greater dispersibility of coating chemicals that are removed from the imaged precursors during development. The amount of polar organic solvent is higher than that found in commercial developers but the presence of the nonionic surfactant reduces phase separation that would normally occur with these higher amounts.

Moreover, the processing steps of the invention are carried out in a processing apparatus in which the working strength processing solution is supplied without replenishment. For example, the working strength processing solution can be supplied from a container or canister that has sufficient processing solution for a single processing cycle. Once processed, the resulting lithographic printing plates have no need of contact with additional solutions, such as rinsing or gumming solutions, before the lithographic printing plates are used for printing.

### BRIEF DESCRIPTION OF THE DRAWING

FIG. 1 is an illustration of a process of the present invention using a useful processing apparatus.

### DETAILED DESCRIPTION OF THE INVENTION

### Definitions

Unless the context indicates otherwise, when used herein, the terms “negative-working lithographic printing plate precursor”, “lithographic printing plate precursor”, “printing plate precursor”, and “precursor” are meant to be references to elements that can be imaged and processed using the present invention.

In addition, unless the context indicates otherwise, the various components described herein such as “sensitizer”, “infrared radiation absorbing compound”, “initiator”, “co-initiator”, “free radically polymerizable component”, “polymeric binder”, “nonionic surfactant”, polar organic solvent”, and various processing solution components described below, also refer to mixtures of such components. Thus, the use of the articles “a”, “an”, and “the” is not necessarily meant to refer to only a single component.

Moreover, unless otherwise indicated, percentages refer to percents by total dry weight, for example, weight % based on total solids of either an imageable layer or radiation-sensitive composition. Unless otherwise indicated, the percentages can be the same for either the dry imageable layer or the total solids of radiation-sensitive composition. When referring to developers as described below, weight % is generally based on the total developer weight including the water and any other solvents that are present.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

The term “polymer” refers to high and low molecular weight polymers including oligomers and includes homopolymers and copolymers.

The term “copolymer” refers to polymers that have two or more different types of recurring units, arranged in random order along the main polymer backbone, unless otherwise defined.

The term “backbone” refers to the chain of atoms (carbon or heteroatoms) in a polymer to which a plurality of pendant groups can be attached. One example of such a backbone is an “all carbon” backbone obtained by the polymerization of one or more ethylenically unsaturated polymerizable monomers. However, other backbones can include heteroatoms wherein the polymer is formed by a condensation reaction or some other means.

### Imaging of Lithographic Printing Plate Precursors

The lithographic printing plate precursors are can be exposed to a suitable source of exposing radiation depending upon the sensitivity of the radiation-sensitive composition, for example, at a wavelength of from about 250 to about 450 nm (“violet” sensitivity) or from about 700 to about 1500 nm (“near IR” and “IR” sensitivity). For example, imaging can be carried out using imaging or exposing radiation when the negative-working lithographic printing plate precursor is IR-sensitive, such as from an infrared laser (or an array of lasers) at a wavelength of at least 700 nm and up to and including about 1400 nm or typically at a wavelength of least 700 nm and up to and including 1200 nm. Imaging can be carried out using imaging radiation at multiple wavelengths at the same time if desired. This imaging provides both exposed (and hardened) regions and non-exposed (developer soluble or developer dispersible) regions in the imageable layer that is disposed on a hydrophilic substrate.

The laser(s) used to expose the lithographic printing plate precursor is usually a diode laser (or array of diode lasers) because of the reliability and low maintenance of diode laser systems, but other lasers such as gas or solid-state lasers may also be used. The combination of power, intensity and exposure time for suitable laser imaging of given imaging chemistry would be readily apparent to one skilled in the art. Presently, high performance lasers or laser diodes used in some commercially available imagesetters emit infrared radiation at a wavelength of at least 800 nm and up to and including 850 nm or at least 1060 and up to and including 1120 nm.

The imaging apparatus can function solely as a platesetter or it can be incorporated directly into a lithographic printing press. In the latter case, printing may commence immediately after imaging and development, thereby reducing press set-up time considerably. The imaging apparatus can be configured as a flatbed recorder or as a drum recorder, with the imageable member mounted to the interior or exterior cylindrical surface of the drum. An example of an useful imaging apparatus is available as models of Kodak Trendsetter platesetters available from Eastman Kodak Company that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen, Chicago, Ill.). Additional useful sources of radiation include direct imaging presses that can be used to image an element while it is attached to the printing plate cylinder. An example of a suitable direct imaging printing press includes the Heidelberg SM74-DI press (available from Heidelberg, Dayton, Ohio). Imaging using near infrared (IR) or infrared (IR) radiation can be carried out generally at imaging energies of at least 30 mJ/cm² and up to and including 500 mJ/cm², and typically of at least 50 and up to and including 300 mJ/cm² depending upon the sensitivity of the imageable layer.

Useful UV and “violet” imaging apparatus include Prosetter (from Heidelberger Druckmaschinen, Germany), Luxel V-8 (from FUJI, Japan), Python (Highwater, UK), MakoNews, Mako 2, Mako 4 or Mako 8 (from ECRM, US), Micra (from Screen, Japan), Polaris and Advantage (from AGFA, Belgium), Laserjet (from Krause, Germany), and Andromeda® A750M (from Lithotech, Germany), imagesetters.

Imaging radiation in the UV to visible region of the spectrum, and particularly the UV region (for example at least 250 nm and up to and including 450 nm) can be carried out generally using energies of at least 0.01 mJ/cm² and up to and including 0.5 mJ/cm², and typically of at least 0.02 and up to and including about 0.1 mJ/cm². It would be desirable, for example, to image the UV/visible radiation-sensitive lithographic printing plate precursors at a power density in the range of at least 0.5 and up to and including 50 kW/cm² and typically of at least 5 and up to and including 30 kW/cm², depending upon the source of energy (violet laser or excimer sources).

While laser imaging is desired in the practice of this invention, thermal imaging can be provided by any other means that provides thermal energy in an imagewise fashion. For example, imaging can be accomplished using a thermoresistive head (thermal printing head) in what is known as “thermal printing”, described for example in U.S. Pat. No. 5,488,025 (Martin et al.). Thermal print heads are commercially available (for example, a Fujitsu Thermal Head FTP-040 MCS001 and TDK Thermal Head F415 HH7-1089).

After imaging, a heating step (pre-heating) can be used to accelerate the formation of a latent image. This heating step can be carried out in so called “preheat units” that can be a separate machine or integrated into the processor that develops the imaged precursor. There are different types of preheat units. The most common ones use infrared radiation or hot air circulation, or combination thereof, to heat the imaged precursor. The temperature used for the purpose is at least 70 and up to and including 200° C. However, it can be advantageous to omit the preheating step to simplify the process for making lithographic printing plates.

A pre-rinse step before processing can be carried out in a stand-alone apparatus or by manually rinsing the imaged precursor with water or a pre-rinse step can be carried out in a washing unit that is integrated in an apparatus used for processing the imaged precursor. However, it is also desirable to omit this step to further simplify the method of this invention.

### Development and Printing

After thermal imaging, the imaged precursors are processed (developed) “off-press” using a single aqueous working strength processing solution that can be a processing solution comprising water (at least 45 weight % and up to and including 90 weight %) as one solvent, and having a pH of at least 7 and up to and including 14, or typically at least 8 and up to and including 12. Processing is carried out for a time sufficient to remove predominantly only the non-exposed regions of the imaged imageable layer of negative-working lithographic printing plate precursors to reveal the hydrophilic surface of the substrate, but not long enough to remove significant amounts of the exposed regions. The revealed hydrophilic surface repels inks while the exposed regions containing polymerized or crosslinked polymer accept ink. Thus, the non-exposed regions to be removed are “soluble” or “removable” in the working strength processing solution because the components of those regions are removed, dissolved, or dispersed within it more readily than the components in the regions that are to remain. The term “soluble” also means “dispersible”.

Processing can be accomplished using what is known as “manual” development, “dip” development, or processing with an automatic development apparatus (processor). In the case of “manual” development, processing is conducted by rubbing the entire imaged precursor with a sponge or cotton pad sufficiently impregnated with the working strength processing solution (described below), contacting the imaged precursor with a roller, impregnated pad, or other applicator, and no rinsing with water is used subsequently. “Dip” development involves dipping the imaged precursor in a tank or tray containing the working strength processing solution for at least 10 and up to and including 60 seconds under agitation. Again, no by rinsing with water is used subsequently. The use of automatic development apparatus is well known and generally includes pumping the working strength processing solution into a tank or ejecting it from spray nozzles. The apparatus can also include a suitable rubbing mechanism (for example a brush, nip rollers, or squeegee) and a suitable number of conveyance rollers. Some developing apparatus include laser exposure means and the apparatus is divided into an imaging section and a developing section. Excess or used working strength processing solution can be collected in the originating or a different container.

In addition, the method of this invention can be carried out by processing the imaged lithographic printing plate precursors by applying the working strength processing solution from a replaceable container (such as a developer canister) without adding water or replenishing it with fresh processing solution. Thus, the total volume of working strength processing solution in the container decreases as processing proceeds. The processing solution is “working strength” so that no dilution is needed before or during its use.

The working strength processing solution can be applied by a spray device (comprising one or more spray nozzles) during part or all of the processing cycle at a rate that is determined by routine experimentation for a given imaged precursor and chemistry. The spraying can be activated in a continuous or intermittent manner. For example, sprayed working strength processing solution can be directed onto the imaged surface of the lithographic printing plate precursor at a distance of at least 1 cm from each imaged precursor surface.

Besides a container for the working strength processing solution, a processing apparatus useful in the practice of this invention can comprise one or more of the following components:

at least one spray device for applying the working strength processing solution to each imaged lithographic printing plate precursor,

at least one pair of rollers (for example squeegee rollers) or a squeegee for removing excess working strength processing solution from each imaged lithographic printing plate precursor after the spraying operation,

a dry cleaning means such as wiping cloth, wiping rollers, or brush, and

a collection device for collecting working strength processing solution that is not carried away by the lithographic printing plates.

After processing, the imaged and processed precursor can be used immediately for lithographic printing, or it can be dry rubbed or otherwise dry cleaned before being used for lithographic printing. This dry cleaning can be carried out using one or more rollers, a squeegee, or dry cloth.

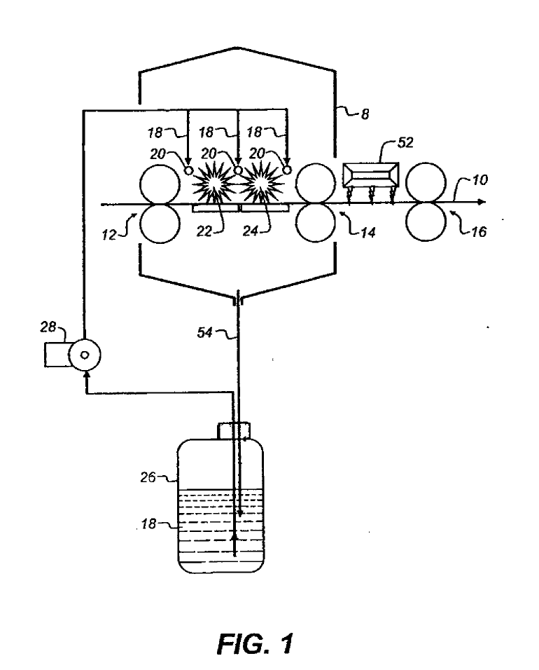

A useful processing apparatus is described in FIG. 1 in which imaged lithographic printing plate precursors are processed in processing chamber 8 while being conveyed in the direction of arrow 10 using conveyance rollers pairs 12, 14, and 16. Between conveyance roller pairs 12 and 14, the conveyed precursors are contacted with working strength processing solution 18 from spray devices 20 while rotating brushes 22 and 24 are used to facilitate removal of non-exposed regions of the imaged surface of the lithographic printing plate precursors. Working strength processing solution 18 is supplied to spray devices 20 from canister 26 using the force from pump 28. The level of working strength processing solution 18 in canister 26 can be monitored using a suitable level sensor. It is also possible to collect used working strength processing solution from processing chamber 8 and return it to canister 26 as shown by arrow 54.

The working strength processing solutions used in this invention commonly include surfactants (at least one nonionic surfactant as described below), antiseptics, defoaming agents, chelating agents (such as salts of ethylenediaminetetraacetic acid), polar organic solvents (such as benzyl alcohol and others described below), and alkaline components (such as organic amines, phosphates, or both). These working strength processing solutions are generally free of silicates and metasilicates, meaning that none of these compounds are purposely added. Generally, these processing solutions are also free of carbonates (including bicarbonates) because none of these compounds is purposely added.

The working strength processing solutions include one or more nonionic surfactants, each having an HLB value greater than 15 and typically at least 15 and up to and including 30. “HLB” is a quantitative measure of the emulsification characteristics of a surfactant and numerically indicates the balance of hydrophilicity (“H” component) and lipophilicity (“L” component) of the surfactant. Thus, “HLB” is an abbreviation of the value of the hydrophile and lipophile balance. An HLB value can be measured using a number of empirical equations, for example equations (1) through (4) described in [0041]-[0046] of U.S. Patent Application Publication 2008/0160452 (Takahashi) that is incorporated herein by reference. For purposes of this invention, the HLB value can be determined by any of these empirical equations and thus, if the HLB value is greater than 15 as determined by any of the empirical equations, it satisfies the present invention. However, in most instances, the HLB value is determined using empirical equation (1) as noted in the Takahashi publication.

Thus, various types of nonionic surfactants can be used in the practice of this invention as long as the HLB value requirement is met. For example, useful nonionic surfactants comprise an aliphatic or aromatic hydrophobic (lipophilic) moiety and an alkylene oxide hydrophilic moiety. Examples of useful nonionic surfactants include but are not limited to, polyoxyethylene alkyl esters, polyoxyethylene alkylphenyl ethers, polyoxyethylene aryl ethers, polyoxyethylene naphthyl ethers, polyoxyethylene-polystyrylphenyl ethers, polyoxyethylenepolyoxypropylene alkyl ethers, partial esters of glycerin and fatty acids, partial esters of sorbitan and fatty acids, partial esters of pentaerythritol and fatty acids, propylene glycol monofatty acid ester, partial esters of sucrose and fatty acids, partial esters of polyoxyethylene sorbitol and fatty acids, esters of polyoxyethylene glycol and fatty acids, partial esters of polyglycerin and fatty acids, polyoxyethylene castor oil, partial esters of polyoxyethyleneglycerin and fatty acids, diethanolamides, triethanolamine fatty acid esters, and trialkylamine oxides. Useful nonionic surfactants are also described in Col. 4, lines 36-52 of U.S. Pat. No. 4,381,340 (noted above) that is incorporated herein by reference. Useful classes of nonionic surfactants include polyoxyethylene alkyl ethers, polyoxypropylene alkyl ethers, polyoxyethylene alkylphenyl ethers, polyoxyethylene aryl ethers, and polyoxyethylene naphthyl ethers.

In addition, fluorine-containing or silicon-containing nonionic surfactants can be used as long as the HLB value is greater than 15.

The one or more nonionic surfactants having the HLB value greater than 15 are present in the working strength processing solution in an amount of at least 2.5 weight % and typically in an amount of at least 4 weight %, and up to and including 15 weight %, or more likely in an amount of at least 5 weight % and up to and including 10 weight %, based on the working strength processing solution weight.

Other surfactants can be included in the working strength processing solution, which surfactants do not have an HLB value greater than 15.

Such optional surfactants can be nonionic, anionic, cationic, or amphoteric in nature. Mixtures of each or several types of such surfactants can be present. Examples of useful optional surfactants are listed for example in [0095], [0100], and [0101] of EP 1,868,036B1 (Baumann et al.) that is incorporated herein by reference. Particularly useful anionic surfactants are described below. However, in some embodiments, the nonionic surfactant having an HLB value greater than 15 is the only surfactant in the working strength processing solution.

The working strength processing solution used in the practice of this invention also includes one or more polar organic solvents in an amount of at least 5 weight %, and typically at least 7 weight % and up to and including 15 weight % based on total working strength processing solution weight. For example, when benzyl alcohol is used as at least one of the polar organic solvents, it can be present in an amount of at least 7 weight % and up to and including 15 weight %.

Thus, useful polar organic solvents include but are not limited to, reaction products of phenol with ethylene oxide and propylene oxide [such as ethylene glycol phenyl ether (phenoxyethanol)], benzyl alcohol, esters of ethylene glycol and of propylene glycol with acids having 6 or less carbon atoms, and ethers of ethylene glycol, diethylene glycol, and of propylene glycol with alkyl groups having 6 or less carbon atoms, such as 2-ethylethanol and 2-butoxyethanol. Benzyl alcohol is particularly useful.

The working strength processing solution used in this invention is used to both develop the imaged precursor by removing predominantly the non-exposed regions and also to provide a protective layer or coating over the entire imaged and developed surface. In this aspect, the working strength processing solution provides gumming or protecting the lithographic image on the printing plate against contamination or damage (for example, from oxidation, fingerprints, dust, or scratches). The working strength processing solution generally includes an organic amine having a boiling point of less than 300° C. (and typically of at least 50° C.) or phosphate, a film-forming hydrophilic polymer, the nonionic surfactant described above, and a polar organic solvent.

Useful organic amines are relatively volatile organic primary, secondary, and tertiary amines that include but are not limited to, alkanolamines (including cycloalkyl amines), carbocyclic aromatic amines, and heterocyclic amines, that are present in a total amount of at least 0.1 weight ° A) and generally up to and including 20 weight %. Useful amines are mono-, di- and trialkanol amines such as monoethanolamine, diethanolamine, triethanolamine, and mono-n-propanolamine, or combinations of these compounds.

One or more film-forming water-soluble or film-forming hydrophilic polymers are present in the aqueous alkaline solution in an amount of at least 0.25 weight % and up to 30 weight % and typically at least 1 and up to and including 15 weight %. Examples of useful polymers of this type include but are not limited to, gum arabic, pullulan, cellulose derivatives (such as hydroxymethyl celluloses, carboxymethylcelluloses, carboxyethylcelluloses, and methyl celluloses), starch derivatives [such as (cyclo)dextrins, starch esters, dextrins, carboxymethyl starch, and acetylated starch] poly(vinyl alcohol), poly(vinyl pyrrolidone), polyhydroxy compounds [such as polysaccharides, sugar alcohols such as sorbitol, miso-inosit, homo- and copolymers of (meth)acrylic acid or (meth)acrylamide], copolymers of vinyl methyl ether and maleic anhydride, copolymers of vinyl acetate and maleic anhydride, copolymers of styrene and maleic anhydride, and copolymers having recurring units with carboxy, sulfo, or phospho groups, or salts thereof. Useful hydrophilic polymers include gum arabic, (cyclo)dextrin, a polysaccharide, a sugar alcohol, and a homo- or copolymer having recurring units derived from (meth)acrylic acid.

Following processing, the resulting lithographic printing plate can be used for printing without a separate rinsing step. The resulting lithographic printing plates are used for printing after development without further contact with any additional solutions such as rinsing or gumming solutions.

If desired, the lithographic printing plates can be dried before they are used for lithographic printing. Drying can be carried out using infrared radiation or hot air. Unlike known methods, no gumming step is needed after drying the lithographic printing plates.

The resulting lithographic printing plate can also be baked in a postbake operation at suitable temperatures and times, with or without a blanket or floodwise exposure to UV or visible radiation using known conditions. Alternatively, a blanket UV or visible radiation exposure can be carried out, without a postbake operation.

Printing can be carried out by applying a lithographic printing ink and fountain solution to the printing surface of the imaged and processed precursor. The fountain solution is taken up by the non-imaged regions, that is, the surface of the hydrophilic substrate revealed by the imaging and processing steps, and the ink is taken up by the imaged (non-removed) regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the lithographic printing plate to the receiving material.

### Substrates

The substrate used to prepare the lithographic printing plate precursors comprises a support that can be composed of any material that is conventionally used to prepare lithographic printing plates. It is usually in the form of a sheet, film, or foil (or web), and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metalized papers), or a lamination of any of these materials (such as a lamination of an aluminum foil onto a polyester film). Metal supports include sheets or foils of aluminum, copper, zinc, titanium, and alloys thereof.

One useful substrate is an aluminum-containing support that can be treated using techniques known in the art, including roughening of some type by physical (mechanical) graining, electrochemical graining, or chemical graining, usually followed by acid anodizing. The aluminum-containing support can be roughened by physical or electrochemical graining and then anodized using phosphoric or sulfuric acid (or a mixture of both phosphoric and sulfuric acids) and conventional procedures. A useful hydrophilic lithographic substrate is an electrochemically grained and sulfuric acid-anodized aluminum-containing substrate that provides a hydrophilic surface for lithographic printing.

Sulfuric acid anodization of the aluminum support generally provides an oxide weight (coverage) on the surface of at least 1.5 and up to and including 5 g/m², and can provide longer press life. Phosphoric acid anodization generally provides an oxide weight on the surface of at least 1 and up to and including 5 g/m².

The aluminum-containing substrate can also be post-treated with, for example, a silicate, dextrin, calcium zirconium fluoride, hexafluorosilicic acid, poly(vinyl phosphonic acid) (PVPA), vinyl phosphonic acid copolymer, poly[(meth)acrylic acid], or an acrylic acid copolymer to increase hydrophilicity. Still further, the aluminum-containing substrate can be treated with a phosphate solution that can further contain an inorganic fluoride (PF). It is particularly useful to post-treat the sulfuric acid-anodized aluminum-containing substrate with either poly(acrylic acid) or poly(vinyl phosphonic acid).

The thickness of the substrate can be varied but should be sufficient to sustain the wear from printing and thin enough to wrap around a printing form. Useful embodiments include a treated aluminum foil having a thickness of at least 100 μm and up to and including 700 μm.

### Negative-Working Lithographic Printing Plate Precursors

The precursors can be formed by suitable application of a radiation-sensitive composition as described below to a suitable substrate (described above) to form an imageable layer. There is generally only a single imageable layer comprising the radiation-sensitive composition and it can be the outermost layer in the element. However, a protective surface topcoat can be present over the imageable layer in some embodiments.

Negative-working lithographic printing plate precursors are described for example, in EP Patent Publications 770,494A1 (Vermeersch et al.), 924,570A1 (Fujimaki et al.), 1,063,103A1 (Uesugi), EP 1,182,033A1 (Fujimako et al.), EP 1,342,568A1 (Vermeersch et al.), EP 1,449,650A1 (Goto), and EP 1,614,539A1 (Vermeersch et al.), U.S. Pat. Nos. 4,511,645 (Koike et al.), 6,027,857 (Teng), 6,309,792 (Hauck et al.), 6,569,603 (Furukawa et al.), 6,899,994 (Huang et al.), 7,045,271 (Tao et al.), 7,049,046 (Tao et al.), 7,261,998 (Hayashi et al.), 7,279,255 (Tao et al.), 7,285,372 (Baumann et al.), 7,291,438 (Sakurai et al.), 7,326,521 (Tao et al.), 7,332,253 (Tao et al.), 7,442,486 (Baumann et al.), 7,452,638 (Yu et al.), 7,524,614 (Tao et al.), 7,560,221 (Timpe et al.), 7,574,959 (Baumann et al.), 7,615,323 (Shrehmel et al.), and 7,672,241 (Munnelly et al.), and U.S. Patent Application Publications 2003/0064318 (Huang et al.), 2004/0265736 (Aoshima et al.), 2005/0266349 (Van Damme et al.), and 2006/0019200 (Vermeersch et al.), all of which are incorporated herein by reference. Other negative-working compositions and elements are described for example in U.S. Pat. Nos. 6,232,038 (Takasaki), 6,627,380 (Saito et al.), 6,514,657 (Sakurai et al.), 6,808,857 (Miyamoto et al.), and U.S. Patent Publication 2009/0092923 (Hayashi), all of which are also incorporated herein by reference.

The radiation-sensitive compositions and imageable layers used in such precursors can generally include one or more polymeric binders that facilitate the developability of the imaged precursors (removal of non-exposed regions). Such polymeric binders include but are not limited to, those that are not generally crosslinkable and are usually present at least partially as discrete particles (not-agglomerated). Such polymers can be present as discrete particles having an average particle size of at least 10 nm and up to and including 500 nm, and typically at least 100 nm and up to and including 450 nm, and that are generally distributed uniformly within that layer. The particulate polymeric binders exist at room temperature as discrete particles, for example in an aqueous dispersion. Such polymeric binders generally have a molecular weight (Mₙ) of at least 5,000 and typically at least 20,000 and up to and including 100,000, or at least 30,000 and up to and including 80,000, as determined by Gel Permeation Chromatography.

Useful particulate polymeric binders generally include polymeric emulsions or dispersions of polymers having hydrophobic backbones to which are directly or indirectly linked pendant poly(alkylene oxide) side chains (for example at least 10 alkylene glycol units), cyano side chains, or both types of side chains, that are described for example in U.S. Pat. Nos. 6,582,882 (Pappas et al.), 6,899,994 (Huang et al.), 7,005,234 (Hoshi et al.), and 7,368,215 (Munnelly et al.) and US Patent Application Publication 2005/0003285 (Hayashi et al.), all of which are incorporated herein by reference. More specifically, such polymeric binders include but are not limited to, graft copolymers having both hydrophobic and hydrophilic segments, block and graft copolymers having polyethylene oxide (PEO) segments, polymers having both pendant poly(alkylene oxide) segments and cyano groups, in recurring units arranged in random fashion to form the polymer backbone, and various hydrophilic polymeric binders that can have various hydrophilic groups such as hydroxyl, carboxy, hydroxyethyl, hydroxypropyl, amino, aminoethyl, aminopropyl, carboxymethyl, sulfono, or other groups readily apparent to a worker skilled in the art.

Alternatively, the particulate polymeric binders can also have a backbone comprising multiple (at least two) urethane moieties. Such polymeric binders generally have a molecular weight (Mₙ) of at least 2,000 and typically at least 100,000 and up to and including 500,000, or at least 100,000 and up to and including 300,000, as determined by dynamic light scattering.

Additional useful polymeric binders are particulate poly(urethane-acrylic) hybrids that are distributed (usually uniformly) throughout the imageable layer. Each of these hybrids has a molecular weight of at least 50,000 and up to and including 500,000 and the particles have an average particle size of at least 10 nm and up to and including 10,000 nm (typically at least 30 and up to and including 500 nm or at least 30 nm and up to and including 150 nm). These hybrids can be either “aromatic” or “aliphatic” in nature depending upon the specific reactants used in their manufacture. Blends of particles of two or more poly(urethane-acrylic) hybrids can also be used. Some poly(urethane-acrylic) hybrids are commercially available in dispersions from Air Products and Chemicals, Inc. (Allentown, Pa.), for example, as the Hybridur® 540, 560, 570, 580, 870, 878, 880 polymer dispersions of poly(urethane-acrylic) hybrid particles. These dispersions generally include at least 30% solids of the poly(urethane-acrylic) hybrid particles in a suitable aqueous medium that can also include commercial surfactants, anti-foaming agents, dispersing agents, anti-corrosive agents, and optionally pigments and water-miscible organic solvents.

These polymeric binders are generally present in an amount of at least 5 and up to and including 70 weight % of the radiation-sensitive composition.

Other useful polymeric binders can be homogenous, that is, non-particulate or dissolved in the coating solvent, or they can exist as discrete particles. Such polymeric binders include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033A1 (Fujimaki et al.) and U.S. Pat. Nos. 6,309,792 (Hauck et al.), 6,352,812 (Shimazu et al.), 6,569,603 (Furukawa et al.), and 6,893,797 (Munnelly et al.), all of which are incorporated herein by reference. Also useful are the vinyl carbazole polymers described in U.S. Pat. No. 7,175,949 (Tao et al.), and the polymers having pendant vinyl groups as described in U.S. Pat. No. 7,279,255 (Tao et al.), both patents being incorporated herein by reference. Useful are random copolymers derived from polyethylene glycol methacrylate/acrylonitrile/styrene monomers in random fashion and in particulate form, dissolved random copolymers derived from carboxyphenyl methacrylamide/acrylonitrile/-methacrylamide/N-phenyl maleimide, random copolymers derived from polyethylene glycol methacrylate/acrylonitrile/vinyl carbazole/styrene/-methacrylic acid, random copolymers derived from N-phenyl maleimide/methacrylamide/methacrylic acid, random copolymers derived from urethane-acrylic intermediate A (the reaction product of p-toluene sulfonyl isocyanate and hydroxylethyl methacrylate)/acrylonitrile/N-phenyl maleimide, and random copolymers derived from N-methoxymethyl methacrylamide/methacrylic acid/acrylonitrile/n-phenylmaleimide. By “random” copolymers, we mean the conventional use of the term, that is, the structural units in the polymer backbone that are derived from the monomers are arranged in random order as opposed to being block copolymers, although two or more of the same structural units can be in a chain incidentally.

Thus, the polymeric binders can be selected from any alkaline solution soluble (or dispersible) polymer having an acid value of at least 20 and up to and including 400 (typically at least 30 and up to and including 200). The following described polymeric binders are particularly useful but this is not an exhaustive list:

I. Polymers formed by polymerization of a combination or mixture of (a) (meth)acrylonitrile, (b) poly(alkylene oxide) esters of (meth)acrylic acid, and optionally (c) (meth)acrylic acid, (meth)acrylate esters, styrene and its derivatives, and (meth)acrylamide as described for example in U.S. Pat. No. 7,326,521 (Tao et al.) that is incorporated herein by reference. Some particularly useful polymeric binders in this class are derived from one or more (meth)acrylic acids, (meth)acrylate esters, styrene and its derivatives, vinyl carbazoles, and poly(alkylene oxide) (meth)acrylates.

II. Polymers having pendant allyl ester groups as described in U.S. Pat. No. 7,332,253 (Tao et al.) that is incorporated herein by reference. Such polymers can also include pendant cyano groups or have recurring units derived from a variety of other monomers as described in Col. 8, line 31 to Col. 10, line 3 of the noted patent.

III. Polymers having all carbon backbones wherein at least 40 and up to and including 100 mol % (and typically at least 40 and up to and including 50 mol %) of the carbon atoms forming the all carbon backbones are tertiary carbon atoms, and the remaining carbon atoms in the all carbon backbone being non-tertiary carbon atoms. Details of such polymeric binders are provided in U.S. Patent Application Publication 2008-0280229 (Tao et al.) that is incorporated herein by reference.

IV. Polymeric binders that have one or more ethylenically unsaturated pendant groups (reactive vinyl groups) attached to the polymer backbone. Such reactive groups are capable of undergoing polymerizable or crosslinking in the presence of free radicals. The pendant groups can be directly attached to the polymer backbone with a carbon-carbon direct bond, or through a linking group (“X”) that is not particularly limited. In some embodiments, the reactive vinyl group is attached to the polymer backbone through a phenylene group as described, for example, in U.S. Pat. No. 6,569,603 (Furukawa et al.) that is incorporated herein by reference. Other useful polymeric binders have vinyl groups in pendant groups that are described, for example in EP 1,182,033A1 (Fujimaki et al.) and U.S. Pat. Nos. 4,874,686 (Urabe et al.), 7,729,255 (Tao et al.), 6,916,595 (Fujimaki et al.), and 7,041,416 (Wakata et al.) all of which are incorporated by reference, especially with respect to the general formulae (1) through (3) noted in EP 1,182,033A1.

V. Polymeric binders can have pendant 1H-tetrazole groups as described in U.S. Patent Application Publication 2009-0142695 (Baumann et al.) that is incorporated herein by reference.

VI. Still other useful polymeric binders can be homogenous, that is, dissolved in the coating solvent, or can exist as discrete particles and include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033 (noted above) and U.S. Pat. Nos. 6,309,792 (Hauck et al.), 6,352,812 (Shimazu et al.), 6,569,603 (noted above), and 6,893,797 (Munnelly et al.) all of which are incorporated herein by reference. Also useful are the vinyl carbazole polymers described in U.S. Pat. No. 7,175,949 (Tao et al.) also incorporated herein by reference.

The radiation-sensitive composition (and imageable layer) includes one or more free radically polymerizable components, each of which contains one or more free radically polymerizable groups that can be polymerized using free radical initiation. For example, such free radically polymerizable components can contain one or more free radical polymerizable monomers or oligomers having one or more addition polymerizable ethylenically unsaturated groups, crosslinkable ethylenically unsaturated groups, ring-opening polymerizable groups, azido groups, aryldiazonium salt groups, aryldiazosulfonate groups, or a combination thereof. Similarly, crosslinkable polymers having such free radically polymerizable groups can also be used. Oligomers or prepolymers, such as urethane acrylates and methacrylates, epoxide acrylates and methacrylates, polyester acrylates and methacrylates, polyether acrylates and methacrylates, and unsaturated polyester resins can be used. In some embodiments, the free radically polymerizable component comprises carboxyl groups.

Free radically polymerizable compounds include those derived from urea urethane (meth)acrylates or urethane (meth)acrylates having multiple polymerizable groups. For example, a free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), Sartomer 355 (di-trimethylolpropane tetraacrylate), Sartomer 295 (pentaerythritol tetraacrylate), and Sartomer 415 [ethoxylated (20)trimethylolpropane triacrylate] that are available from Sartomer Company, Inc.

Numerous other free radically polymerizable components are known to those skilled in the art and are described in considerable literature including Photoreactive Polymers: The Science and Technology of Resists, A Reiser, Wiley, New York, 1989, pp. 102-177, by B. M. Monroe in Radiation Curing: Science and Technology, S. P. Pappas, Ed., Plenum, New York, 1992, pp. 399-440, and in “Polymer Imaging” by A. B. Cohen and P. Walker, in Imaging Processes and Material, J. M. Sturge et al. (Eds.), Van Nostrand Reinhold, New York, 1989, pp. 226-262. For example, useful free radically polymerizable components are also described in EP 1,182,033A1 (Fujimaki et al.), beginning with paragraph [0170], and in U.S. Pat. Nos. 6,309,792 (Hauck et al.), 6,569,603 (Furukawa), and 6,893,797 (Munnelly et al.). Other useful free radically polymerizable components include those described in U.S. Patent Application Publication 2009/0142695 (Baumann et al.), which radically polymerizable components include 1H-tetrazole groups.

In addition to, or in place of the free radically polymerizable components described above, the radiation-sensitive composition can include polymeric materials that include side chains attached to the backbone, which side chains include one or more free radically polymerizable groups (such as ethylenically unsaturated groups) that can be polymerized (crosslinked) in response to free radicals produced by the initiator composition (described below). There can be at least two of these side chains per molecule. The free radically polymerizable groups (or ethylenically unsaturated groups) can be part of aliphatic or aromatic acrylate side chains attached to the polymeric backbone. Generally, there are at least 2 and up to and including 20 such groups per molecule.

Such free radically polymerizable polymers can also comprise hydrophilic groups including but not limited to, carboxy, sulfo, or phospho groups, either attached directly to the backbone or attached as part of side chains other than the free radically polymerizable side chains.

The radiation-sensitive composition also includes an initiator composition that includes one or more initiators that are capable of generating free radicals sufficient to initiate polymerization of all the various free radically polymerizable components upon exposure of the composition to imaging infrared radiation. The initiator composition is generally responsive, for example, to electromagnetic radiation in the infrared spectral regions, corresponding to the broad spectral range of at least 700 nm and up to and including 1400 nm, and typically radiation of at least 700 nm and up to and including 1250 nm. Alternatively, the initiator composition may be responsive to exposing radiation in the violet region of at least 250 and up to and including 450 nm and typically at least 300 and up to and including 450 nm.

More typically, the initiator composition includes one or more an electron acceptors and one or more co-initiators that are capable of donating electrons, hydrogen atoms, or a hydrocarbon radical.

In general, suitable initiator compositions for radiation-sensitive compositions comprise initiators that include but are not limited to, aromatic sulfonylhalides, trihalogenomethylsulfones, imides (such as N-benzoyloxyphthalimide), diazosulfonates, 9,10-dihydroanthracene derivatives, N-aryl, S-aryl, or O-aryl polycarboxylic acids with at least 2 carboxy groups of which at least one is bonded to the nitrogen, oxygen, or sulfur atom of the aryl moiety (such as aniline diacetic acid and derivatives thereof and other “co-initiators” described in U.S. Pat. No. 5,629,354 of West et al.), oxime ethers and oxime esters (such as those derived from benzoin), α-hydroxy or α-amino-acetophenones, trihalogenomethyl-arylsulfones, benzoin ethers and esters, peroxides (such as benzoyl peroxide), hydroperoxides (such as cumyl hydroperoxide), azo compounds (such as azo bis-isobutyronitrile), 2,4,5-triarylimidazolyl dimers (also known as hexaarylbiimidazoles, or “HABI's”) as described for example in U.S. Pat. No. 4,565,769 (Dueber et al.), trihalomethyl substituted triazines, boron-containing compounds (such as tetraarylborates and alkyltriarylborates) and organoborate salts such as those described in U.S. Pat. No. 6,562,543 (Ogata et al.), and onium salts (such as ammonium salts, diaryliodonium salts, triarylsulfonium salts, aryldiazonium salts, and N-alkoxypyridinium salts).

Hexaarylbiimidazoles, onium compounds, and thiol compounds as well as mixtures of two or more thereof are desired coinitiators or free radical generators, and especially hexaarylbiimidazoles and mixtures thereof with thiol compounds are useful. Suitable hexaarylbiimidazoles are also described in U.S. Pat. Nos. 4,565,769 (Dueber et al.) and 3,445,232 (Shirey) and can be prepared according to known methods, such as the oxidative dimerization of triarylimidazoles.

Useful initiator compositions for IR radiation-sensitive compositions include onium compounds including ammonium, sulfonium, iodonium, and phosphonium compounds. Useful iodonium cations are well known in the art including but not limited to, U.S. Patent Application Publication 2002/0068241 (Oohashi et al.), WO 2004/101280 (Munnelly et al.), and U.S. Pat. Nos. 5,086,086 (Brown-Wensley et al.), 5,965,319 (Kobayashi), and 6,051,366 (Baumann et al.). For example, a useful iodonium cation includes a positively charged iodonium, (4-methylphenyl)[4-(2-methylpropyl)phenyl]-moiety and a suitable negatively charged counterion.

Thus, the iodonium cations can be supplied as part of one or more iodonium salts, and the iodonium cations can be supplied as iodonium borates also containing suitable boron-containing anions. For example, the iodonium cations and the boron-containing anions can be supplied as part of substituted or unsubstituted diaryliodonium salts that are combinations of Structures (I) and (II) described in Cols. 6-8 of U.S. Pat. No. 7,524,614 (Tao et al.) that is incorporated herein by reference. Useful IR radiation-sensitive initiator compositions can comprise one or more diaryliodonium borate compounds. Mixtures of two or more of these compounds can also be used in the initiator composition.

The imageable layers comprise a radiation-sensitive imaging composition that includes one or more infrared radiation absorbing compounds or one or more UV sensitizers. The total amount of one or more infrared radiation absorbing compounds or sensitizers is at least 1 and up to and including 30 weight %, or typically at least 5 and up to and including 20 weight %, based on the imageable layer total solids.

In some embodiments, the radiation-sensitive composition contains a UV sensitizer where the free-radical generating compound is UV radiation sensitive (that is at least 150 nm and up to and including 475 nm), thereby facilitating photopolymerization. In some other embodiments, the radiation sensitive compositions are sensitized to “violet” radiation in the range of at least 375 nm and up to and including 475 nm. Useful sensitizers for such compositions include certain pyrilium and thiopyrilium dyes and 3-ketocoumarins. Some other useful sensitizers for such spectral sensitivity are described for example, in 6,908,726 (Korionoff et al.), WO 2004/074929 (Baumann et al.) that describes useful bisoxazole derivatives and analogues, and U.S. Patent Application Publications 2006/0063101 and 2006/0234155 (both Baumann et al.).

Still other useful sensitizers are the oligomeric or polymeric compounds having Structure (I) units defined in WO 2006/053689 (Strehmel et al.) that have a suitable aromatic or heteroaromatic unit that provides a conjugated π-system between two heteroatoms.

Additional useful “violet”-visible radiation sensitizers are the compounds described in WO 2004/074929 (Baumann et al.). These compounds comprise the same or different aromatic heterocyclic groups connected with a spacer moiety that comprises at least one carbon-carbon double bond that is conjugated to the aromatic heterocyclic groups, and are represented in more detail by Formula (I) of the noted publication.

Other useful sensitizers for the violet region of sensitization are the 2,4,5-triaryloxazole derivatives as described in WO 2004/074930 (Baumann et al.). These compounds can be used alone or with a co-initiator as described above. Useful 2,4,5-triaryloxazole derivatives can be represented by the Structure G-(Ar₁)₃ wherein Ar₁ is the same or different, substituted or unsubstituted carbocyclic aryl group having 6 to 12 carbon atoms in the ring, and G is a furan or oxazole ring, or the Structure G-(Ar₁)₂ wherein G is an oxadiazole ring. The Ar₁ groups can be substituted with one or more halo, substituted or unsubstituted alkyl, substituted or unsubstituted cycloalkyl, substituted or unsubstituted aryl, amino (primary, secondary, or tertiary), or substituted or unsubstituted alkoxy or aryloxy groups. Useful substituents for each Ar₁ group include the same or different primary, secondary, and tertiary amines.

Still another class of useful violet radiation sensitizers includes compounds represented by the Structure Ar₁-G-Ar₂ wherein Ar₁ and Ar₂ are the same or different substituted or unsubstituted aryl groups having 6 to 12 carbon atoms in the ring, or Ar₂ can be an arylene-G-Ar₁ or arylene-G-Ar₂ group, and G is a furan, oxazole, or oxadiazole ring. Ar₁ is the same as defined above, and Ar₂ can be the same or different aryl group as Ar₁. “Arylene” can be any of the aryl groups defined for Ar₁ but with a hydrogen atom removed to render them divalent in nature.

Some useful infrared radiation absorbing compounds are sensitive to both infrared radiation (typically of at least 700 nm and up to and including 1400 nm) and visible radiation (typically of at least 450 nm and up to and including 700 nm). These compounds also have a tetraaryl pentadiene chromophore. Such chromophore generally includes a pentadiene linking group having 5 carbon atoms in the chain, to which are attached two substituted or unsubstituted aryl groups at each end of the linking group. These aryl groups can be substituted with the same or different tertiary amine groups. Other details of such compounds are provided in U.S. Pat. No. 7,429,445 (Munnelly et al.).

Other useful include but are not limited to, azo dyes, squarilium dyes, croconate dyes, triarylamine dyes, thioazolium dyes, indolium dyes, oxonol dyes, oxaxolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, cryptocyanine dyes, naphthalocyanine dyes, polyaniline dyes, polypyrrole dyes, polythiophene dyes, chalcogenopyryloarylidene and bi(chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. Nos. 5,208,135 (Patel et al.), 6,153,356 (Urano et al.), 6,264,920 (Achilefu et al.), 6,309,792 (Hauck et al.), 6,569,603 (noted above), 6,787,281 (Tao et al.), 7,135,271 (Kawaushi et al.), and EP 1,182,033A2 (noted above) Infrared radiation absorbing N-alkylsulfate cyanine dyes are described for example in U.S. Pat. No. 7,018,775 (Tao). A general description of one class of suitable cyanine dyes is shown by the formula in paragraph [0026] of WO 2004/101280 (Munnelly et al.).

In addition to low molecular weight IR-absorbing dyes having IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. Nos. 6,309,792 (noted above), 6,264,920 (Achilefu et al.), 6,153,356 (noted above), and 5,496,903 (Watanabe et al.). Suitable dyes can be formed using conventional methods and starting materials or obtained from various commercial sources including American Dye Source (Baie D'Urfe, Quebec, Canada) and FEW Chemicals (Germany). Other useful dyes for near infrared diode laser beams are described in U.S. Pat. No. 4,973,572 (DeBoer).

Useful IR-radiation sensitive compositions are described, for example, in U.S. Pat. No. 7,452,638 (Yu et al.), and U.S. Patent Application Publications 2008/0254387 (Yu et al.), 2008/0311520 (Yu et al.), 2009/0263746 (Ray et al.), and 2010/0021844 (Yu et al.) all of which are incorporated herein by reference.

The imageable layer can also include a poly(alkylene glycol) or an ether or ester thereof that has a molecular weight of at least 200 and up to and including 4000. The imageable layer can further include a poly(vinyl alcohol), a poly(vinyl pyrrolidone), poly(vinyl imidazole), or polyester in an amount of up to and including 20 weight % based on the total dry weight of the imageable layer.

Additional additives to the imageable layer include color developers or acidic compounds such as monomeric phenolic compounds, organic acids or metal salts thereof, oxybenzoic acid esters, acid clays, and other compounds described for example in U.S. Patent Application Publication 2005/0170282 (Inno et al.). The imageable layer can also include a variety of optional compounds including but not limited to, dispersing agents, humectants, biocides, plasticizers, surfactants for coatability or other properties, viscosity builders, pH adjusters, drying agents, defoamers, preservatives, antioxidants, development aids, rheology modifiers or combinations thereof, or any other addenda commonly used in the lithographic art, in conventional amounts. The imageable layer also optionally includes a phosphate (meth)acrylate having a molecular weight generally greater than 250 as described in U.S. Pat. No. 7,429,445 (Munnelly et al.) that is incorporated herein by reference.

The radiation-sensitive composition can be applied to the substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying onto a suitable support (such as an on-press printing cylinder). Typically, the radiation-sensitive composition is applied and dried to form an imageable layer.

An outermost overcoat (also sometimes known as an “oxygen impermeable topcoat” or “oxygen barrier layer”) can be disposed over the imageable layer. Such overcoat layers can comprise one or more water-soluble poly(vinyl alcohol)s having a saponification degree of at least 90% and generally have a dry coating weight of at least 0.1 and up to and including 2 g/m² in which the water-soluble poly(vinyl alcohol)s comprise at least 60% and up to and including 99% of the dry overcoat layer weight. The overcoat can further comprise a second water-soluble polymer that is not a poly(vinyl alcohol) in an amount of from about 2 to about 38 weight %, and such second water-soluble polymer can be a poly(vinyl pyrrolidone), poly(ethyleneimine), poly(vinyl imidazole), poly(vinyl caprolactone), or a random copolymer derived from two or more of vinyl pyrrolidone, ethyleneimine, vinyl caprolactone, and vinyl imidazole, and vinyl acetamide.

Alternatively, the overcoat can be formed predominantly using one or more of polymeric binders such as poly(vinyl pyrrolidone), poly(ethyleneimine), poly(vinyl imidazole), and random copolymers from two or more of vinyl pyrrolidone, ethyleneimine and vinyl imidazole, and mixtures of such polymers. The formulations can also include cationic, anionic, and non-ionic wetting agents or surfactants, flow improvers or thickeners, antifoamants, colorants, particles such as aluminum oxide and silicon dioxide, and biocides. Details about such addenda are provided in WO 99/06890 (Pappas et al.) that is incorporated by reference.

Such manufacturing methods can include mixing the various components needed for a specific imaging chemistry in a suitable organic solvent or mixtures thereof [such as methyl ethyl ketone (2-butanone), methanol, ethanol, 1-methoxy-2-propanol, iso-propyl alcohol, acetone, γ-butyrolactone, n-propanol, tetrahydrofuran, and others readily known in the art, as well as mixtures thereof], applying the resulting solution to a substrate, and removing the solvent(s) by evaporation under suitable drying conditions. Some representative coating solvents and imageable layer formulations are described in the Invention Examples below. After proper drying, the coating weight of the imageable layer is generally at least 0.1 and up to and including 5 g/m² or at least 0.5 and up to and including 3.5 g/m².

Layers can also be present under the imageable layer to enhance developability or to act as a thermal insulating layer.

Once the various layers have been applied and dried on the substrate, the negative-working imageable elements can be enclosed in water-impermeable material that substantially inhibits the transfer of moisture to and from the element and “heat conditioned” as described in U.S. Pat. No. 7,175,969 (noted above) that is incorporated herein by reference.

The lithographic printing plate precursors can be stored and transported as stacks of precursors within suitable packaging and containers known in the art.

The present invention provides at least the following embodiments and combinations thereof, but other combinations of features are considered to be within the present invention as a skilled artisan would appreciate from the teaching of this disclosure:

1. A method for preparing a plurality of lithographic printing plates, comprising:

imaging a plurality of negative-working lithographic printing plate precursors comprising free radical imaging chemistry to provide a plurality of imaged precursors,

processing each of the imaged precursors in a processing apparatus comprising a working strength processing solution that comprises at least 2.5 weight % of a nonionic surfactant having a HLB value greater than 15 and at least 5 weight % of a polar organic solvent, by applying the working strength processing solution to each imaged precursor to provide a lithographic printing plate having a printing surface,

wherein the processing solution is not replenished during processing of the plurality of imaged precursors, the processing solution is designed to both develops each imaged precursor and to provide a protective coating over the printing surface of the lithographic printing plate, and the plurality of imaged precursors are contacted with no additional solutions after processing with the working strength processing solution before they are used for lithographic printing.

2. The method of embodiment 1 wherein the nonionic surfactant has an HLB value of at least 15 and up to and including 30.

3. The method of embodiment 1 or 2 wherein working strength processing solution comprises the polar organic solvent in an amount of at least 7 weight % and up to and including 15 weight %.

4. The method of any of embodiments 1 to 3 wherein the nonionic surfactant is present in the working strength processing solution in an amount of at least 4 weight % and up to and including 15 weight %.

5. The method of any of embodiments 1 to 4 wherein the nonionic surfactant is the only surfactant in the working strength processing solution.

6. The method of any of embodiments 1 to 5 wherein the working strength processing solution is free of silicates and metasilicates.

7. The method of any of embodiments 1 to 6 wherein the each negative-working lithographic printing plate precursor is IR-sensitive and imaging is carried out using infrared radiation at a wavelength of at least 700 nm and up to and including 1400 nm.

8. The method of any of embodiments 1 to 7 wherein at least some of the plurality of negative-working lithographic printing plate precursors comprise a protective surface topcoat.

9. The method of any of embodiments 1 to 8 wherein the working strength processing solution comprises a polar organic solvent that is one or more compounds selected from the group consisting of benzyl alcohol, a reaction product of phenol with ethylene oxide or propylene oxide, and an ester of ethylene glycol or propylene glycol with an acid having 6 or less carbon atoms.

10. The method of any of embodiments 1 to 9 wherein the working strength processing solution comprises an organic amine or a phosphate, or both an organic amine and a phosphate, and is free of carbonates.

11. The method of any of embodiments 1 to 10 wherein the nonionic surfactant comprises an aliphatic or aromatic hydrophobic moiety and an alkylene oxide hydrophilic moiety.

12. The method of embodiment 11 wherein the nonionic surfactant is selected from the group consisting of polyoxyethylene alkyl esters, polyoxypropylene alkyl ethers, polyoxyethylene alkylphenyl ethers, polyoxyethylene aryl ethers, and polyoxyethylene naphthyl ethers.

13. The method of any of embodiments 1 to 12 wherein the working strength processing solution comprises benzyl alcohol in an amount of at least 7 weight % and up to and including 15 weight %.

14. The method of any of embodiments 1 to 13 wherein the working strength processing solution is provided in the processing apparatus in a replaceable canister.

15. The method of any of embodiments 1 to 14 wherein the processing apparatus further comprises:

at least one spray device for applying the working strength processing solution to each imaged precursor,

at least one pair of nip rollers or a squeegee for removing excess working strength processing solution from each imaged precursor after the working strength developer is sprayed thereon,

a dry cleaning means such as wiping cloth, wiping rollers, or brush, and

a collection device for collecting working strength processing solution that is not carried away by the lithographic printing plates.

16. The method of any of embodiments 1 to 15 wherein the working strength processing solution has a pH of at least 7 and up to and including 14.

17. The method of any of embodiments 1 to 16 wherein each imaged precursor is processed by spraying the working strength processing solution at a distance of at least 1 cm from the surface of each imaged precursor.

18. The method of any of embodiments 1 to 17 wherein each imaged is dry rubbed after processing before being used for lithographic printing.

19. The method of any of embodiments 1 to 18 further comprising using the lithographic printing plate for lithographic printing without contact with any additional solutions after processing.

The following Examples are provided to illustrate the practice of this invention and are not meant to be limiting in any manner.

The surfactants shown in TABLE I below were evaluated in developers in terms of their hydrotropic capability and emulsifying properties at high developer loading. Each developer was prepared having the following components:

Developer Formulation:

5.0 weight % of benzyl alcohol

7.5 weight % of surfactant from TABLE I

1.0 weight % of ethanolamine

0.5 weight % of sodium diphosphate

5.0 weight % of Sorbidex™ sorbitol

81.0 weight % of water

pH of about 11
Emulan OP25 and Emulan TO40 were obtained from BASF.
Triton® X45 was obtained from Dow Chemical Company.
Lutensol TO10 was obtained from BASF.
Lugalvan® BNO12 was obtained from BASF.

### Invention Examples 1-4 and Comparative Examples 1-4

The left side of TABLE I shows surfactants with HLB values >15 (for Invention Examples 1-4 going down the column) while the right side of TABLE I shows similar surfactants with shorter EO units and thus HLB values <15 (Comparative Examples 1-4 doing down the column). The results from the evaluations are provided with each surfactant.

Samples of negative-working lithographic printing plate precursors were used in this evaluation. The imageable layer coatings of 25 such precursor samples (13×18 cm size) were removed and added to 50 ml of each developer to provide a “loaded” developer for a “microloading test”. Each loaded developer was added to a glass tube and sludge formation and phase separation were evaluated after 24 hours.

Some selected developer samples with certain surfactants were subjected to a complete loading test (processing “cycle test”) in a W860SP processor prototype from Eastman Kodak Company. The developer volume was 10 liters and the cycle volume was 250 m².

The negative-working, IR-sensitive, free radical chemistry imageable layer formulation used in the evaluations was prepared by dissolving or dispersing the following components:
2.5 g of Hybridur® 580 urethane-acrylic hybrid polymer dispersion (Air Products)
3.0 g of SR399 (from Sartomer)
1.7 g of Cu-phthalocyanine pigment dispersion
0.2 g of bis(4-t-butylphenyl)-iodonium tetraphenylborate
0.1 g of IR dye 2-[2-[3-[2-(1,3-Dihydro-1,3,3-trimethyl-2H-indol-2-ylidene)-ethylidene]-2-(1-phenyl-1H-tetrazol-5-ylsulfanyl)-1-cyclohexen-1-yl]-ethenyl]-1,3,3-trimethyl-3H-indolium chloride,
in 2.0 g of γ-butyrolactone, 8.0 g of methyl ether ketone, and 7.0 g of Dowanol® PM as a solvent mixture.

This imageable layer formulation was coated onto an electrochemically grained and anodized aluminium substrate that had been post-treated with poly(vinyl phosphonic acid) to provide a dry coating weight of about 1.2 g/m². Onto this dried imageable layer, a protective topcoat layer was applied from a formulation comprising 1.0 g of poly(vinyl alcohol) having a viscosity of 4 mPa's and 88% degree of hydrolysis, in 50 g of water to provide a dry coating weight of 0.5 g/m².

Prior to development, the negative-working lithographic printing plate precursors were placed on a Kodak® Trendsetter 800 II Quantum platesetter (830 nm) using a test image with defined tonal values for evaluating the quality of development and exposed at 80 mJ/cm² using an 830 nm IR laser.

TABLE I

| High HLB >15 | Low HLB <15 |
|---|---|
| 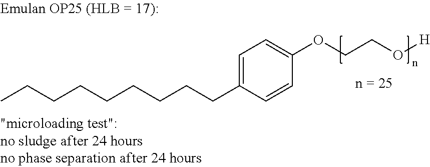 | 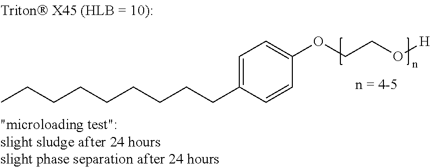 |
| 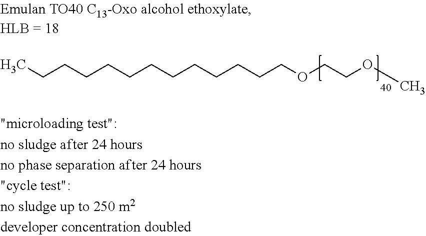 | 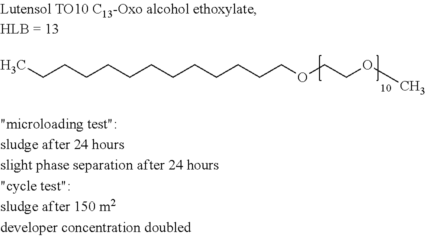 |
| 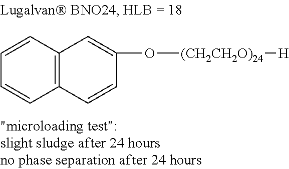 | 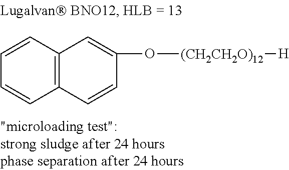 |

These results demonstrate that by using nonionic surfactants having an HLB value greater than 15, the processing cycle time is maximized and sludge formation is reduced. Thus, cleaning operations can be less frequent.

### Comparative Example 5

A developer formulation was prepared for evaluation having the following composition:

### Developer Formulation

5.0 weight % of benzyl alcohol

2.0 weight % of Emulan TO40

1.0 weight % of ethanolamine

0.5 weight % of sodium diphosphate

5.0 weight % of Sorbidex™ sorbitol

81.0 weight % of water

Lithographic printing plate precursors were imaged and developed as described above using this developer formulation. During a “microloading test”, the processed lithographic printing plates showed coating retentions in the fine screens, considerable sludge after 24 hours, and a phase separation after 24 hours. These poor results were evident when the nonionic surfactant having an HLB value >15 was present at a concentration less than 2.5 weight %.

### Comparative Example 6

A developer formulation was prepared for evaluation having the following formulation:

### Developer Formulation

2.0 weight % of benzyl alcohol

7.5 weight % of Emulan TO40

1.0 weight % of ethanolamine

0.5 weight % of sodium diphosphate

5.0 weight % of Sorbidex™ sorbitol

81.0 weight % of water

Lithographic printing plate precursors were imaged and processed as described above using this developer formulation. The imaged precursors were not developable in this developer formulation and heavy and prolonged scrubbing was needed to remove the imaged regions. These poor results were evident because benzyl alcohol was present at a concentration less than 5 weight %.

### Invention Example 5

A developer formulation useful in the present invention was prepared having the following composition:

### Developer Formulation

5.0 weight % of benzyl alcohol

10.0 weight % of Emulan TO40

1.0 weight % of ethanolamine

0.5 weight % of sodium diphosphate

5.0 weight % of Sorbidex™ sorbitol

81.0 weight % of water

Lithographic printing plate precursors were imaged and processed as described above using this developer formulation. In a “microloading test”, no sludge or phase separation was observed after 24 hours. During a “cycle test”, no sludge was observed for up to 250 m² of processed precursor, while the developer concentration was doubled. These desired results were evident at the higher concentration of the nonionic surfactant having an HLB value >15.

### Invention Example 6

A developer formulation was prepared for evaluation for use in the present invention using the following composition:

### Developer Formulation

5.0 weight % of benzyl alcohol

10.0 weight % of Emulan TO40

1.0 weight % of ethanolamine

0.5 weight % of sodium diphosphate

5.0 weight % of Sorbidex™ sorbitol

81.0 weight % of water

Lithographic printing plate precursors were imaged and processed as described above using this developer formulation. During a “microloading test”, no sludge or phase separation was observed after 24 hours. During a “cycle test”, no sludge was observed for up to 250 m² of processed precursor while the developer concentration was doubled.

The invention has been described in detail with particular reference to certain preferred embodiments thereof, but it will be understood that variations and modifications can be effected within the spirit and scope of the invention.

### PARTS LIST

8 Processing chamber
10 Arrow showing conveyance direction
12, 14, 16 Roller pairs
18 Developer
20 Spray devices
22, 24 Rotating brushes
26 Developer canister
28 Developer pump
52 Drying chamber
54 Arrow to show used developer

1. A method for preparing a plurality of lithographic printing plates, comprising:
imaging a plurality of negative-working lithographic printing plate precursors comprising free radical imaging chemistry to provide a plurality of imaged precursors,
processing each of the imaged precursors in a processing apparatus comprising a working strength processing solution that comprises at least 2.5 weight % of a nonionic surfactant having a HLB value greater than 15 and at least 5 weight % of a polar organic solvent, by applying the working strength processing solution to each imaged precursor to provide a lithographic printing plate having a printing surface,
wherein the processing solution is not replenished during processing of the plurality of imaged precursors, the processing solution is designed to both develops each imaged precursor and to provide a protective coating over the printing surface of the lithographic printing plate, and the plurality of imaged precursors are contacted with no additional solutions after processing with the working strength processing solution before they are used for lithographic printing.

2. The method of claim 1 wherein the nonionic surfactant has an HLB value of at least 15 and up to and including 30.

3. The method of claim 1 wherein working strength processing solution comprises the polar organic solvent in an amount of at least 7 weight % and up to and including 15 weight %.

4. The method of claim 1 wherein the nonionic surfactant is present in the working strength processing solution in an amount of at least 4 weight % and up to and including 15 weight %.

5. The method of claim 1 wherein the nonionic surfactant is the only surfactant in the working strength processing solution.

6. The method of claim 1 wherein the working strength processing solution is free of silicates and metasilicates.

7. The method of claim 1 wherein the each negative-working lithographic printing plate precursor is IR-sensitive and imaging is carried out using infrared radiation at a wavelength of at least 700 nm and up to and including 1400 nm.

8. The method of claim 1 wherein at least some of the plurality of negative-working lithographic printing plate precursors comprise a protective surface topcoat.

9. The method of claim 1 wherein the working strength processing solution comprises a polar organic solvent that is one or more compounds selected from the group consisting of benzyl alcohol, a reaction product of phenol with ethylene oxide or propylene oxide, and an ester of ethylene glycol or propylene glycol with an acid having 6 or less carbon atoms.

10. The method of claim 1 wherein the working strength processing solution comprises an organic amine or a phosphate, or both an organic amine and a phosphate, and is free of carbonates.

11. The method of claim 1 wherein the nonionic surfactant comprises an aliphatic or aromatic hydrophobic moiety and an alkylene oxide hydrophilic moiety.

12. The method of claim 11 wherein the nonionic surfactant is selected from the group consisting of polyoxyethylene alkyl esters, polyoxypropylene alkyl ethers, polyoxyethylene alkylphenyl ethers, polyoxyethylene aryl ethers, and polyoxyethylene naphthyl ethers.

13. The method of claim 1 wherein the working strength processing solution comprises benzyl alcohol in an amount of at least 7 weight % and up to and including 15 weight %.

14. The method of claim 1 wherein the working strength processing solution is provided in the processing apparatus in a replaceable canister.

15. The method of claim 1 wherein the processing apparatus further comprises:
at least one spray device for applying the working strength processing solution to each imaged precursor,
at least one pair of nip rollers or a squeegee for removing excess working strength processing solution from each imaged precursor after the working strength developer is sprayed thereon,
a dry cleaning means such as wiping cloth, wiping rollers, or brush, and
a collection device for collecting working strength processing solution that is not carried away by the lithographic printing plates.

16. The method of claim 1 wherein the working strength processing solution has a pH of at least 7 and up to and including 14.

17. The method of claim 1 wherein each imaged precursor is processed by spraying the working strength processing solution at a distance of at least 1 cm from the surface of each imaged precursor.

18. The method of claim 1 wherein each imaged is dry rubbed after processing before being used for lithographic printing.

19. The method of claim 1 further comprising using the lithographic printing plate for lithographic printing without contact with any additional solutions after processing.
